(19) United States
(12) Patent Application Publication
(10) Pub. No.: US 2008/0067490 A1
(43) Pub. Date: Mar. 20, 2008

(54) Phase-change memory device having heater electrode with improved heat generation efficiency

(75) Inventor: Tsutomu Hayakawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/902,008

(22) Filed: Sep. 18, 2007

(30) Foreign Application Priority Data
Sep. 19, 2006 (JP) 2006-252506

(51) Int. Cl. H01L 45/00

(52) U.S. Cl. 257/4; 438/102; 257/E45.002

(57) ABSTRACT

A phase-change memory device according to the present invention includes a phase-change layer, a stacked heater electrode electrically connected to the phase-change layer, and a contact plug electrically connected to the stacked heater electrode. The stacked heater electrode includes at least a first electrode portion made of a first electrically conductive material and a second electrode portion provided in contact with the inner side of the first electrode portion. The second electrode portion is made of a second electrically conductive material having a resistivity lower than the resistivity of the first electrically conductive material.

This application is based upon and claims the benefit of priority from Japanese Patent Application No. 2006-252506 filed on Sep. 19, 2006, the content of which is incorporated by reference.

### BACKGROUND OF THE INVENTION

1. Field of the Invention

The present invention relates to a phase-change memory device and a method for manufacturing the phase-change memory device.

2. Description of the Related Art

A phase-change memory device is a device that uses as its memory cells a phase-change layer which changes its electrical resistance depending on the condition of the crystal. A material such as a chalcogenide semiconductor film is used for the phase-change layer. A chalcogenide semiconductor is an amorphous semiconductor containing a chalcogen element.

Chalcogens are group 6 elements, namely S (sulfur), Se (selenium), and Te (tellurium). Applications of chalcogenide semiconductors are divided into two broad categories: optical disk and electric memory. Known chalcogenide semiconductors used in electric memory applications include GeSbTe (hereinafter referred to as GST) which is a compound of Ge (gelmanium), Te, and Sb (antimony), include AsSbTe, or SeSbTe.

FIGS. 1A and 1B are diagrams illustrating a principle of a phase-change memory. FIG. 1A is a graph showing the correlation between the spatial arrangement of atoms and free energy in a chalcogenide semiconductor. The vertical axis represents the magnitude of free energy and the horizontal axis represents the spatial arrangement of atoms.

As shown in FIG. 1A, the chalcogenide semiconductor can take two stable states: amorphous state 10 and crystalline state 30. For switching from amorphous state 10 to crystalline state 30, the chalcogenide semiconductor needs application of heat that exceeds energy barrier 20.

As shown in FIG. 1B, the amorphous state exhibits a higher electrical resistance, which is used to represent a digital value “1”. The crystalline state exhibits a lower electrical resistance, which is used to represent a digital value “0”. Thus, the chalcogenide semiconductor can be caused to store either of the two digital values as digital information. A difference in the amount of current flowing through the chalcogenide semiconductor (or a voltage drop across the chalcogenide semiconductor) can be detected to determine whether the information stored in the chalcogenide semiconductor is “1” or “0”.

Heat supplied to cause a phase change in the chalcogenide semiconductor is Joule heat. Pulses having different peak values and different pulse durations are applied to the chalcogenide semiconductor to generate Joule heat in the vicinity of contact surfaces of the electrodes and the chalcogenide semiconductor, and the Joule heat causes a phase change.

Specifically, after the chalcogenide semiconductor is supplied with heat at a temperature near its melting point in a short time, the chalcogenide semiconductor is quickly cooled to switch it into the amorphous state. On the other hand, after the chalcogenide semiconductor is supplied with heat at a crystallizing temperature lower than the melting point for a long period of time, the chalcogenide semiconductor is cooled to switch it into the crystalline state.

For example, after the GST is supplied with heat at a temperature near its melting point, which is approximately 610° C., for a short period of time (1 to 10 ns), the GST is quickly cooled (for approximately 1 ns) to cause the GST to switch into the amorphous state. On the other hand, after the GST is supplied with heat at its crystallizing temperature (approximately 450° C.) for a long period of time (30 to 50 ns), the GST is cooled to cause the GST to switch into the crystalline state.

This will be described in further detail. Switching of a chalcogenide semiconductor from the amorphous state into the crystalline state is referred to as the crystallizing process; switching of the chalcogenide semiconductor from the crystalline state into the amorphous state is referred to as amorphizing process.

An operation for causing a chalcogenide semiconductor to switch from the amorphous state into the crystalline state is referred to as a “setting operation” and a pulse applied to the chalcogenide semiconductor is referred to as a “setting pulse”. When a setting pulse is applied to the chalcogenide semiconductor, heat higher than or equal to the crystallizing temperature Tc, which is the minimum temperature required to crystallize the chalcogenide semiconductor, is applied to the chalcogenide semiconductor for the minimum crystallizing time tr required for crystallizing the chalcogenide semiconductor.

On the other hand, an operation for causing the chalcogenide semiconductor to change from the crystalline state into the amorphous state is referred to as a “resetting operation” and a pulse applied to reset the chalcogenide semiconductor is referred to as a “resetting pulse”. When a resetting pulse is applied to the chalcogenide semiconductor, the chalcogenide semiconductor is supplied with heat near the melting point Tm. After the chalcogenide semiconductor melts, the chalcogenide semiconductor is rapidly quenched.

As shown in FIG. 1B, when a resetting operation is applied to the chalcogenide semiconductor in the amorphous state, the chalcogenide semiconductor switches into the crystalline state. Conversely, when a resetting operation is applied to the chalcogenide semiconductor in the crystalline state, the chalcogenide semiconductor switches into the amorphous sate.

FIG. 2A is a diagram illustrating a basic structure of a phase-change memory device; FIGS. 2B through 2D illustrate a manner in which the phase-change memory device is set and reset.

As shown in FIG. 2A, the phase-change memory device has a basic structure in which chalcogenide semiconductor layer 46 is sandwiched between upper electrode 48 and lower electrode 42. Chalcogenide semiconductor layer 46 in FIG. 2A is the phase-change layer. In FIG. 2A, electrode 42, electric insulating film 44, chalcogenide semiconductor layer 46, and electrode 48 are stacked on substrate 40 in this order. Electric insulating film 44 covers the side surfaces of the electrode 42, and the upper surface of electrode 42 except a portion of the upper surface. Chalcogenide semiconductor layer 46 is in contact with electrode 42 through an opening in electric insulating film 44 on the electrode 42. Electrode 48 covers the side surfaces and upper surface of chalcogenide semiconductor layer 46.

Upper electrode 48 is connected to a terminal P0 to which a setting pulse will be applied. Lower electrode 42 is connected to ground (reference potential).

The phase-change memory device shown in FIG. 2A is equivalent to resistance R1 shown in FIG. 2B. As described above, the resistivity of resistance R1 varies depending on whether the phase-change layer is in the amorphous state or the crystalline state. As shown in the left part of FIG. 2B, setting pulse S1, resetting pulse S2, and reading pulse S3 are input to terminal P0.

Setting pulse S1 has a peak value greater than threshold Vth. Resetting pulse S2 has a peak value greater than that of setting pulse S1 and has a smaller pulse width. Reading pulse S3 has a peak value smaller than the threshold Vth and has a wider pulse width than that of setting pulse S1. The threshold Vth represents the minimum voltage at which Joule heat required for crystallization can be generated.

FIG. 2C shows the relationship between setting pulse S1 and temperature rise caused by the Joule heat that is generated when setting pulse S1 is supplied. In FIG. 2C, the upper curve represents the waveform of the voltage, and the lower curve represents temperature rise caused by Joule heat. The horizontal axis of either graph represents time.

The voltage value of setting pulse S1 is greater than the threshold Vth and the duration is tcry, which is greater than or equal to the crystallizing time tr, which is the minimum time required to crystallize the chalcogenide semiconductor. The temperature rise due to the Joule heat is considerably lower than the melting point Tm and higher than the crystallizing temperature Tc, which is the minimum temperature required for crystallizing the chalcogenide semiconductor.

FIG. 2D is a graph of resetting pulse S2 versus temperature rise caused by application of resetting pulse S2. The upper curve in FIG. 2D represents the voltage waveform and the lower curve represents the temperature rise caused by Joule heat. The horizontal axis of either graph represents time.

As shown, the peak value of the resetting pulse S2 is much higher than the threshold value Vth for crystallization and the pulse duration is sufficiently short. The temperature rise due to Joule heat is in excess of melting point Tm of the chalcogenide semiconductor. The temperature falls from the peak value to crystallizing temperature Tc within sufficiently short time tamo. Therefore, after the chalcogenide semiconductor is melted, it is quenched so that it returns to the amorphous state.

While the phase-change memory device described above has a circuit arrangement for supplying setting pulse S1 and resetting pulse S2 from terminal P0, the phase-change memory device may have a circuit arrangement as described below.

FIG. 3 is a circuit diagram showing an exemplary circuit arrangement of the phase-change memory device.

In FIG. 3, resistance R1 is equivalent to the phase-change memory device and has a terminal P0 connected to a power supply potential VDD. Size-adjusted MOS transistors M1, M2, and M3 are connected in parallel. The drain electrodes of the MOS transistors are connected to resistance R1 and the sources are connected to ground. The gate electrodes of MOS transistors M1, M2, and M3 are connected to terminals P1, P2, and P3, respectively. Terminal P1 is a setting pulse terminal, terminal P2 is a resetting pulse terminal, and terminal P3 is a reading pulse terminal.

A voltage is applied to terminal P1, P2, or P3 to select MOS transistor M1, M2, or M3 to turn on, and also to control the turn-on time of the selected MOS transistor. In this manner, setting, resetting, and read operations can be implemented.

FIG. 4 is a circuit diagram illustrating a read operation in a phase-change memory device (phase-change memory IC). The same components in FIG. 4 as those shown in FIG. 3 are labeled with the same reference characters.

One of the two terminals of resistance R1 which represents an equivalent resistance in the phase-change memory device including chalcogenide semiconductor layer 60 is connected to a bit line BL. The bit line BL is a pulse input line to be connected to a terminal P0 for inputting setting pulse S1, resetting pulse S2, and reading pulse S3. The other terminal of the two terminals of resistance R1 is connected to the drain electrode of NMOS transistor (switching element) M4 for selecting a memory cell.

The gate electrode of the NMOS transistor M4 is connected to a word line WL, and the source electrode is connected to a positive input terminal of sense amplifier A1 and to the ground through current-to-voltage converting resistance R2. The negative input terminal of sense amplifier A1 is connected to the ground through reference voltage source 62. Voltage Vout represents an output voltage (sensing output) of sense amplifier A1. Current I1 represents current flowing through the memory cell in a read operation.

Operation of the phase-change memory device shown in FIG. 4 will be briefly described below.

In a setting operation, the word line WL is activated to turn on NMOS transistor M4. Then, setting pulse S1 is input through terminal P0. In a resetting operation, resetting pulse S2 is input through terminal P0 in a manner similar to this. In a read operation, reading pulse S3 is input through terminal P0 in a similar manner.

The resistivity of resistance R1 varies depending on whether chalcogenide semiconductor layer 60 forming the memory cell is in the amorphous state or the crystalline state. The amount of current I1 flowing in a read operation varies accordingly. Therefore, by converting the amount of current I1 into a voltage and reading the voltage, it is possible to determine whether information stored in the memory cell is “1” or “0”.

FIG. 5 is a cross-sectional view showing an example of a specific structure of a memory cell of the phase-change memory device.

As shown in FIG. 5, n-type layers 71 and 72 are formed on p-type semiconductor silicon substrate 70 and gate electrode 74 is provided on gate insulating film 73. N-type layer 71 is a source electrode and n-type layer 72 is a drain electrode. Gate electrode 74 is connected to a word line WL.

Interlayer insulating films 75 and 79 are formed in layers on gate insulating film 73. Contact plugs 76 and 77 are provided in and pass through interlayer insulating film 75. The material of contact plugs 76 and 77 may be tungsten (W), for example. Provided in interlayer insulating film 79 is electrode 78, which is a first conductor layer. N-type layer 71 is connected to electrode 78 through contact plug 76. Electrode 78 is connected to a ground line GND.

Provided in interlayer insulating film 79 is contact plug 80 that passes through film 79. N-type layer 72 is connected to contact plug 80 through contact plug 77. Contact plug 80 may be made of a titanium nitride (TiN) film, for example.

Formed on interlayer insulating film 79 is adhering layer 81 made of a very thin metal film. Phase-change layer 82 made of a chalcogenide semiconductor is formed on adhering layer 81. Adhering layer 81 is provided in order to increase the strength of adhesion between phase-change layer 82 and interlayer insulating layer 79 because the degree of adhesion between them are not so good.

Upper electrode 83, which is a second conductor layer, is provided on phase-change layer 82 to cover the top surface of phase-change layer 82. Interlayer insulating film 84 is formed on upper electrode 83. Contact electrode 85 is provided in and passes through interlayer insulating film 84. Provided on interlayer insulating film 84 is electrode 86, which is a third conductor layer. Upper electrode 83 is connected to electrode 86 through contact electrode 85. Electrode 86 functions as a pulse supplying terminal P0.

A region in phase-change layer 82 enclosed in a dashed line X0 in FIG. 5 is a region where a phase change occurs. Electrode 80 embedded in interlayer insulating film 79 constricts current flowing through phase-change layer 82 to increase the current density for efficiently generating Joule heat in phase-change region X0. Hence, electrode 80 is called a heater electrode.

A phase-change memory device with a phase-change layer sandwiched between upper and lower electrodes as shown in FIG. 2A is disclosed in Japanese Patent Laid-Open No. 2006-74028, for example. The publication also discloses a heater electrode made of titanium nitride (TiN) and a heater electrode made of titanium aluminum nitride (TiAlN).

In order to efficiently cause a phase change of phase-change layer 82, the efficiency of heat generation by heater electrode 80 must be increased. To that end, reduction in the diameter of heater electrode 80 and increase of the resistance of heater electrode 80 are effective methods.

However, there are limitations to reducing the diameter of heater electrode 80 because of the precision of photolithography. Therefore attempts have been made in the past few years to make the diameter of heater electrode 80 smaller by using a spacer made of an insulating film formed inside a contact hole used for forming heater electrode 80 after the contact hole is provided.

With the phase-change memory device having the spacer, it is technically possible to reduce the diameter of heater electrode 80. However, the phase-change memory device has problems in that the number of process steps is increased by the addition of the process step for forming the spacer and in that the yield is decreased due to defective contact holes.

On the other hand, increasing the resistance of heater electrode 80 can increase the efficiency of heat generation by heater electrode 80 and therefore reduce reset current. However, this method has a problem in that the voltage drop by heater electrode 80 increases. Accordingly, a sufficient voltage cannot be supplied to a transistor that functions as a switching element for selecting a memory cell and a malfunction can occur in the phase-change memory device.

Increasing the sizes of transistors in order to avoid the malfunction makes it difficult to densely arrange the transistors in the phase-change memory device.

### SUMMARY OF THE INVENTION

An object of the present invention is to provide a phase-change memory device that prevents reduction in manufacturing yields and reduces voltage drop caused by a heater electrode, and a method for manufacturing the phase-change memory device.

A phase-change memory device according to the present invention includes: a phase-change layer, a stacked heater electrode electrically connected to the phase-change layer; and a contact plug electrically connected to the stacked heater electrode, wherein the stacked heater electrode comprises at least: a first electrode portion made of a first electrically conductive material; and a second electrode portion provided in contact with the inner side of the first electrode portion, the second electrode portion being made of a second electrically conductive material having a resistivity lower than the resistivity of the first electrically conductive material.

According to the present invention, the heater electrode does not need to be designed excessively small, therefore reduction in manufacturing yields can be prevented. Furthermore, the efficiency of heat generation by the hater electrode is increased and therefore reset current is reduced and voltage drop by the heater electrode can be minimized.

The above and other objects, features and advantages of the present invention will become apparent from the following description with reference to the accompanying drawings which illustrate examples of the present invention.

### BRIEF DESCRIPTION OF THE DRAWINGS

FIGS. 1A and 1B are diagrams illustrating a principle of phase-change memory;

FIG. 2A is a diagram illustrating a basic structure of the phase-change memory device;

FIGS. 2B to 2D are diagrams illustrating setting/resetting operations of the phase-change memory device;

FIG. 3 is a circuit diagram showing an exemplary circuit arrangement of the phase-change memory device;

FIG. 4 is a circuit diagram illustrating a read operation in the phase-change memory device;

FIG. 5 is a schematic cross-sectional view illustrating a relevant part of a related phase-change memory device;

FIG. 6 is a schematic diagram showing an example of a feature structure of a phase-change memory device according to a first exemplary embodiment of the present invention;

FIG. 7 is a schematic cross-sectional view showing an exemplary stacked heater electrode;

FIG. 8 is a schematic cross-sectional view showing an exemplary stacked heater electrode;

FIGS. 9A and 9B are schematic cross-sectional views of major processing steps, illustrating a method for manufacturing the stacked heater electrode according to the first exemplary embodiment;

FIG. 10 is a schematic cross-sectional view of major processing steps, illustrating a method for manufacturing a stacked heater electrode according to a third exemplary embodiment;

FIG. 11 is a schematic cross-sectional view illustrating an example of a phase-change memory device according to a fourth exemplary embodiment of the present invention;

FIG. 12 is a circuit diagram showing a configuration of the entire circuit of the phase-change memory device according to the fourth exemplary embodiment of the present invention;

FIG. 13 is a top view of the phase-change memory device shown in FIG. 12, showing an exemplary layout of elements and wiring in a memory cell region;

FIG. 14 is a schematic cross-sectional view of the phase-change memory device at a first processing step, taken along line A—A′ of FIG. 13;

FIG. 15 is a schematic cross-sectional view of the phase-change memory device at a second processing step, taken along line A—A′ of FIG. 13;

FIG. 16 is a schematic cross-sectional view of the phase-change memory device at a third processing step, taken along line A—A′ of FIG. 13; and

FIG. 17 is a schematic cross-sectional view of the phase-change memory device at fourth to sixth processing steps, taken along line A—A′ of FIG. 13.

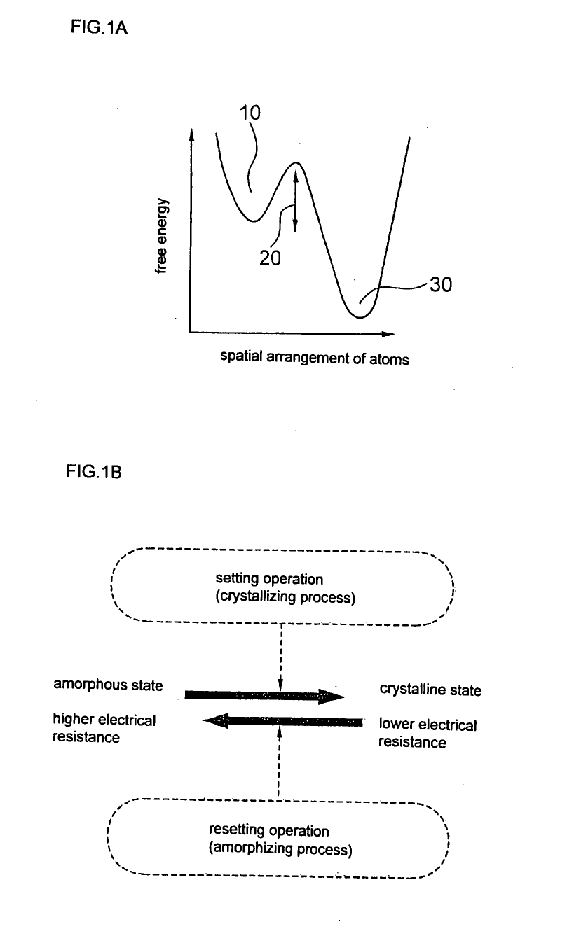

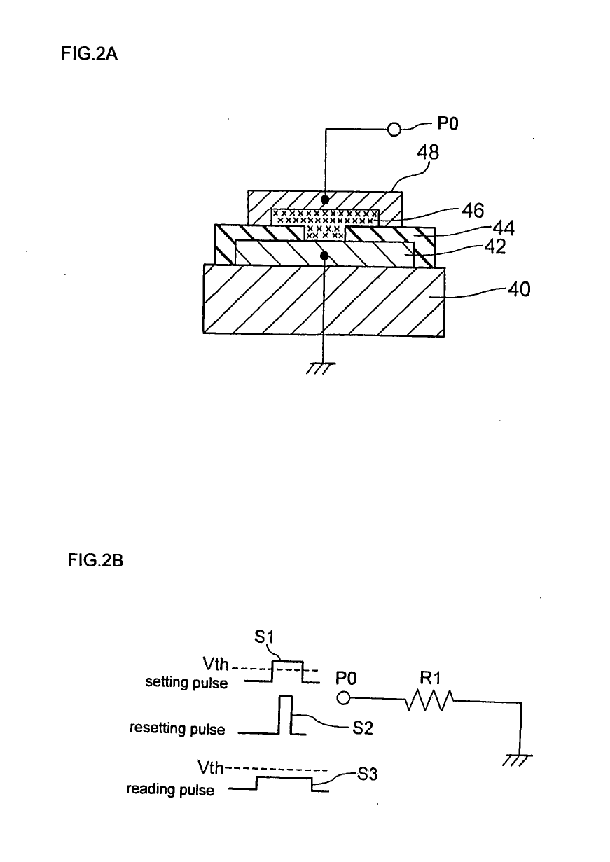

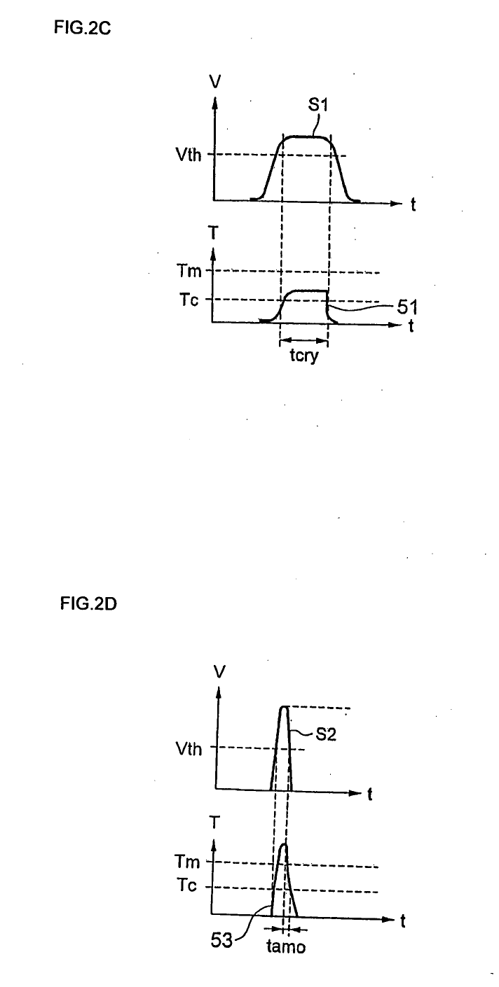

### DETAILED DESCRIPTION OF THE PREFERRED EMBODIMENTS

### First Exemplary Embodiment

A first exemplary embodiment of the present invention will be described with reference to the accompanying drawings.

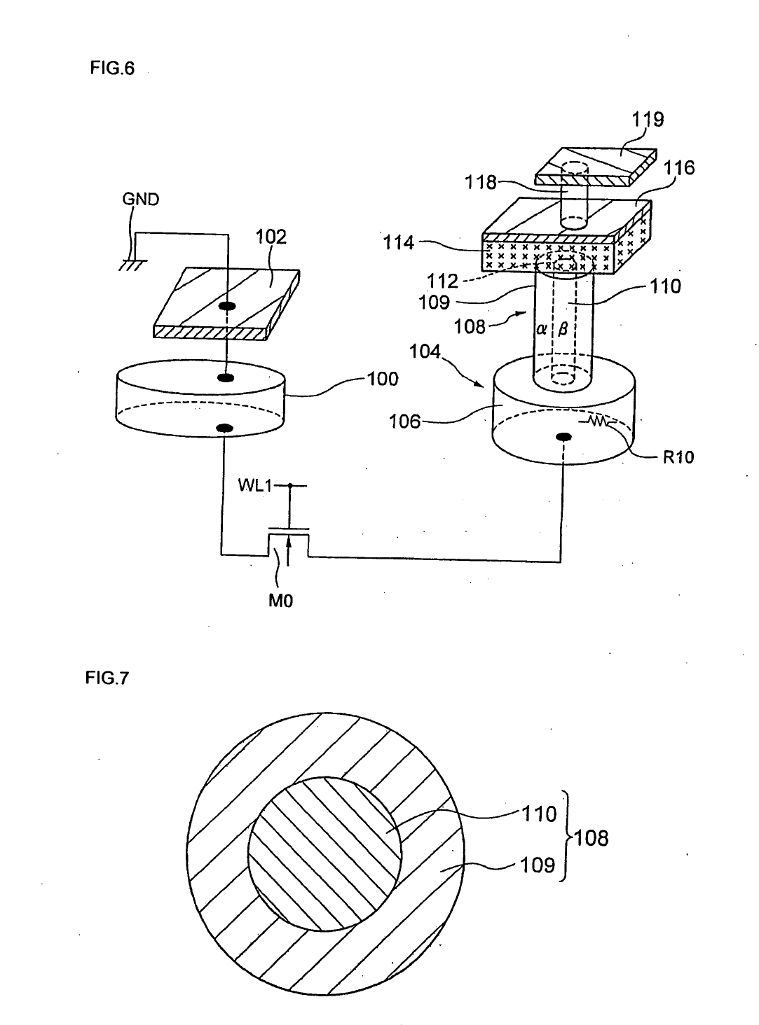

FIG. 6 is a schematic diagram showing an example of a feature structure of a phase-change memory device according to the first exemplary embodiment of the present invention. In FIG. 6, an NMOS transistor (n-channel insulated-gate field-effect transistor) M0 is a switching element for selecting a memory cell and has a gate electrode connected to word line WL1.

The source electrode of the NMOS transistor M0 is electrically connected to a ground potential GND through ground potential metal plug 100 and ground potential line 102. The ground potential is the reference potential.

The drain electrode of the NMOS transistor M0 is electrically connected to contact plug 104 made of a material such as tungsten 106.

The bottom surface of stacked heater electrode 108 is in contact with the top surface of contact plug 104.

The top surface of stacked heater electrode 108 is in contact with the bottom surface of phase-change layer 114. A region near contact surface 112 between stacked heater electrode 108 and phase-change layer 114 is a phase-change region in phase-change layer 114 where a phase change occurs.

The phase-change layer may be made of GST.

Upper electrode (electrode layer) 116 is formed on the top surface of phase-change layer 114. Upper electrode 116 is connected to electrode terminal 119 through contact plug 118.

Stacked heater electrode 108 includes first electrode portion 109 made of a first electrically conductive material a and second electrode portion 110 made of a second electrically conductive material p provided in contact with the inner side of first electrode portion 109 as shown in FIG. 6. Second electrode portion 110 has a cylindrical shape. First electrode portion 109 has a cylindrical shape, formed around second electrode portion 110 to a uniform thickness.

The resistivity of the second electrically conductive material β is smaller than that of the first electrically conductive material α. That is, the interior of stacked heater electrode 108 has a resistivity lower than that of the exterior.

The resistivity of the first electrically conductive material α and the resistivity of the second electrically conductive material p may be constant values. Alternatively, the resistivity may gradually decrease from that of the first electrically conductive material a to that of the second electrically conductive material β.

FIG. 7 is a schematic cross-sectional view of a relevant part of stacked heater electrode 108, taken along a plane parallel with a semiconductor substrate on which NMOS transistor M0 is provided.

As shown in FIG. 7, stacked heater electrode 108 has outer, first electrode portion 109 made of the first electrically conductive material having a higher resistivity and inner, second electrode portion 110 made of the second electrically conductive material having a lower resistivity.

When the resistivity of the second electrically conductive material is lower than that of the first electrically conductive material in the present invention, two types of electrode portions appear in a cross section of the first and second electrode portions taken along a plane parallel with the semiconductor substrate. The resistivities of the first and second electrically conductive materials that appeared are compared with each other to determine which of them is higher.

For convenience of explanation, stacked heater electrode 108 is shown as having two electrode portions, namely first electrode portion 109 made of the first electrically conductive material and second electrode portion 110 made of the second electrically conductive material, in FIGS. 6 and 7. However, stacked heater electrode 108 is not limited to one that includes two electrode portions.

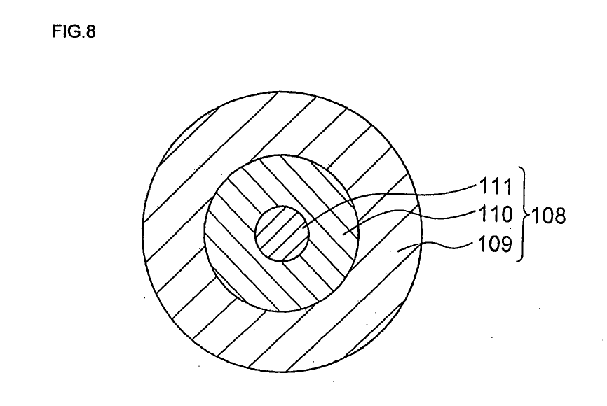

FIG. 8 is a schematic cross-sectional view of a relevant part of stacked heater electrode 108, taken along a plane parallel with a semiconductor substrate on which NMOS transistor M0 is provided.

As shown in FIG. 8, stacked heater electrode 108 may include three or more electrode portions, such as second electrode portion 110 made of a second conductive material encompassing third electrode portion 111 made of a third electrically conductive material. In this case, the resistivities satisfy the relationship R1>R2>R3, where R1, R2, and R3 denote the resistivities of the first, second, and third electrically conductive materials, respectively.

The same applies to a stacked heater electrode including two or more electrode portions in the following description.

The first electrically conductive material may be an electrically conductive element, a nitride of an electrically conductive element, or a silicide of an electrically conductive element, for example.

Examples of electrically conductive elements include titanium, tantalum, molybdenum, niobium, zirconium, tungsten, and carbon.

Examples of nitrides of electrically conductive elements include titanium nitrides such as TiN, TiBN, TiON, TiAlON, and TiCN, tantalum nitrides such as TaN, TaAlN, TaON, and TaCN, molybdenum nitrides such as MoN and MoAlN, niobium nitrides such as NbN, zirconium nitrides such as ZrAlN, tungsten nitrides such as WBN and WON, and carbon nitrides such as CN.

Examples of silicides of electrically conductive elements include titanium silicides such as TiSiN, tantalum silicides such as TaSiN, molybdenum silicides such as MoSiN, niobium silicides such as NbSiN, zirconium silicides such as ZrSiN, tungsten silicides such as WSiN, and carbon silicides such as TiSiC.

One or more materials may be used as the first electrically conductive material.

The second electrically conductive material may be an electrically conductive element, a nitride of an electrically conductive element, or a silicide of an electrically conductive element.

Examples of electrically conductive elements include titanium, tantalum, molybdenum, niobium, zirconium, tungsten, and carbon.

Examples of nitrides of electrically conductive elements include titanium nitrides such as TiN, TiBN, TiON, TiAlON, and TiCN, tantalum nitrides such as TaN, TaAlN, TaON, and TaCN, molybdenum nitrides such as MoN and MoAlN, niobium nitrides such as NbN, zirconium nitrides such as ZrAlN, tungsten nitrides such as WBN and WON, and carbon nitrides such as CN.

Examples of silicides of electrically conductive elements include titanium silicides such as TiSiN, tantalum silicides such as TaSiN, molybdenum silicides such as MoSiN, niobium silicides such as NbSiN, zirconium silicides such as ZrSiN, tungsten silicides such as WSiN, and carbon silicides such as TiSiC.

One or more materials may be used as the second electrically conductive material. The same applies to the third or more electrically conductive material.

The resistivity of the first electrically conductive material is preferably in the range from 300 to 20,000 μΩ·cm, more preferably in the range from 350 to 10,000 μΩ·cm, and most preferably in the range from 400 to 8,000 μΩ·cm.

The resistivity of the second electrically conductive material is preferably in the rang from 10 to 2,000 μΩ·cm, more preferably in the range from 100 to 1,000 μΩ·cm, and most preferably in the range from 150 to 1,000 μΩ·cm.

A third electrically conductive material can be chosen that has a resistivity lower than that of the second electrically conductive material, as appropriate.

The resistivity of the first electrically conductive material is preferably at least ten times that of the second electrically conductive material.

Without reducing the area of a cross section of the stacked heater electrode shown in FIG. 7 or 8, the use of the structure of stacked heater electrode 108 described above can increase the efficiency of heat generation of the entire stacked heater electrode 108 as compared with a heater electrode made of a electrically conductive material having a uniform resistivity.

Thus, the structure of the phase-change memory device according to the present invention does not require having an excessively small design of the stacked heater electrode and therefore can prevent reduction in the manufacturing yields of the phase-change memory device of the present invention.

Furthermore, since an electrically conductive material having a low resistivity is provided in stacked heater electrode 108, voltage drop in the phase-change memory device caused by the stacked heater electrode 108 can be minimized. Thus, a phase-change memory device that is highly reliable and capable of achieving a high package density can be provided.

### Second Exemplary Embodiment

An example of a method for manufacturing a stacked heater electrode described with respect to the first exemplary embodiment will be described in the second exemplary embodiment.

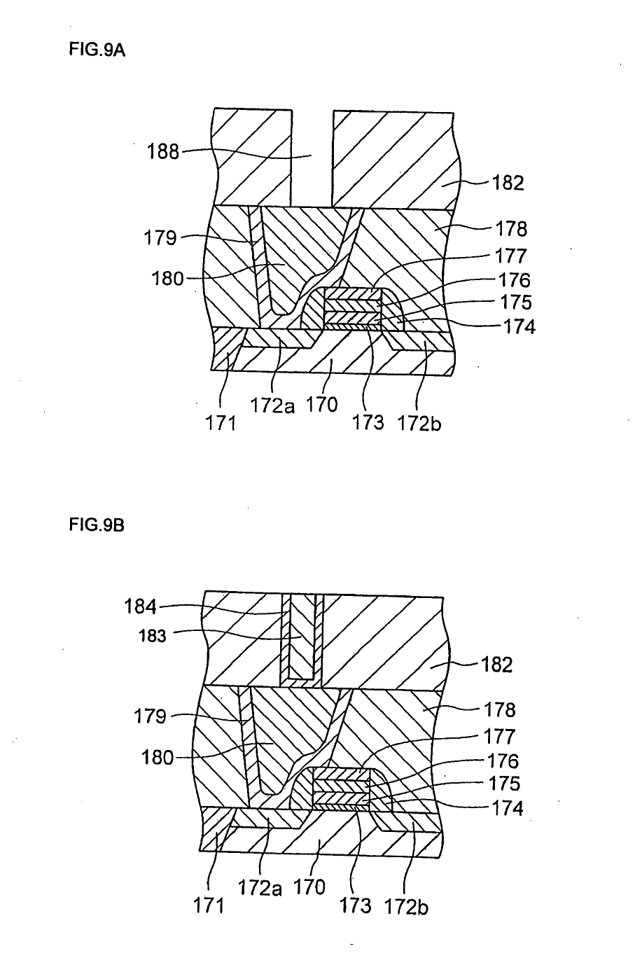

FIGS. 9A and 9B are schematic cross-sectional views of a relevant part of a stacked heater electrode at major processing steps, for illustrating a method for manufacturing the stacked heater electrode. The following description focuses on a method for manufacturing the stacked heater electrode and description of a method for forming transistors and contact plugs provided in layers below the stacked heater electrode will be omitted. A configuration of layers below interlayer insulating film 182 shown in FIG. 9A will be described later with respect to a fourth exemplary embodiment.

As shown in FIG. 9A, interlayer insulating film 182 is deposited on the top surface of a contact plug 180 by using a technique such as high-density plasma (HDP). Then, a portion of interlayer insulating film 182 is selectively etched to provide contact hole 188.

Contact hole 188 can be formed by using a well-known etching technique. One example will be described. A photoresist (not shown) is applied onto interlayer insulating film 182, the photoresist layer is patterned using a photolithography method to form an opening in a position in the photoresist layer where contact hole 188 is to be provided. The patterned photoresist layer is used as a mask to etch interlayer insulating film 182. Thus, the portion of interlayer insulating film 182 is selectively etched.

A film of TiN is deposited on the inner side and bottom surfaces of the contact hole by a Metal Organic-Chemical Vapor Deposition (MO-CVD) method with Ti [N(CH₃)₂]₄ to a thickness in the range from 1 to 30 nm, preferably in the range from 5 to 15 nm.

Then, a N₂ gas flow of 200 ml/min and a H₂ gas flow of 300 ml/min start to flow in an atmosphere at a temperature of 450° C. and a pressure of 1.5 Torr to apply plasma processing to the TiN film for 5 to 35 seconds. The resistivity of the TiN film can be set in any value in the range from 400 to 6,200 μΩ·cm in accordance with the processing time of the plasma processing.

It should be noted that plasma processing is highly anisotropic and therefore the resistivity of the TiN film at the inner bottom surface of contact hole 188 can be made sufficiently small compared with that of TiN at the inner side surface of contact hole 188.

In this way, first electrode portion 184 made of the first electrically conductive material is formed in the contact hole as shown in FIG. 9B.

Then, TiN is deposited on the exposed surface of first electrode portion 184 made of the first electrically conductive material to a thickness in the range from 20 to 80 nm, preferably in the range from 40 to 60 nm using a CVD with TiCl. By the CVD process, the space in contact hole 188 except first electrode portion 184 is filled with TiN generated by the CVD method.

TiN generated by the CVD method contains fewer impurities than TiN generated by a MO-CVD method. Accordingly, a lower resistivity of TiN generated by the CVD method than that of TiN generated by the MO-CVD method can be achieved.

Then, portions of first and second electrode portions 184 and 183 formed above interlayer insulating film 182 are polished away using CMP (Chemical-Mechanical Polishing) to complete a stacked heater electrode.

As a result of these processing steps, second electrode portion 183 made of a second electrically conductive material having a smaller resistivity than that of the first electrically conductive material can be formed in contact with the inner surface of the first electrode portion as shown in FIG. 9B.

According to the manufacturing method of the exemplary embodiment, by adding a phase-change layer on the stacked heater electrode separately, the upper end of each of first electrode portion 184 and second electrode portion 183 can be brought into contact with the phase-change layer.

In addition, first electrode portion 184 can be provided so that the lower end of the first electrode portion 184 is in contact with contact plug 180 as shown in FIG. 9B.

Furthermore, the lower end of second electrode portion 183 can be electrically connected to contact plug 180 through first electrode portion 184.

### Third Exemplary Embodiment

In a third exemplary embodiment, another exemplary method for manufacturing a stacked heater electrode will be described that differs from the second exemplary embodiment.

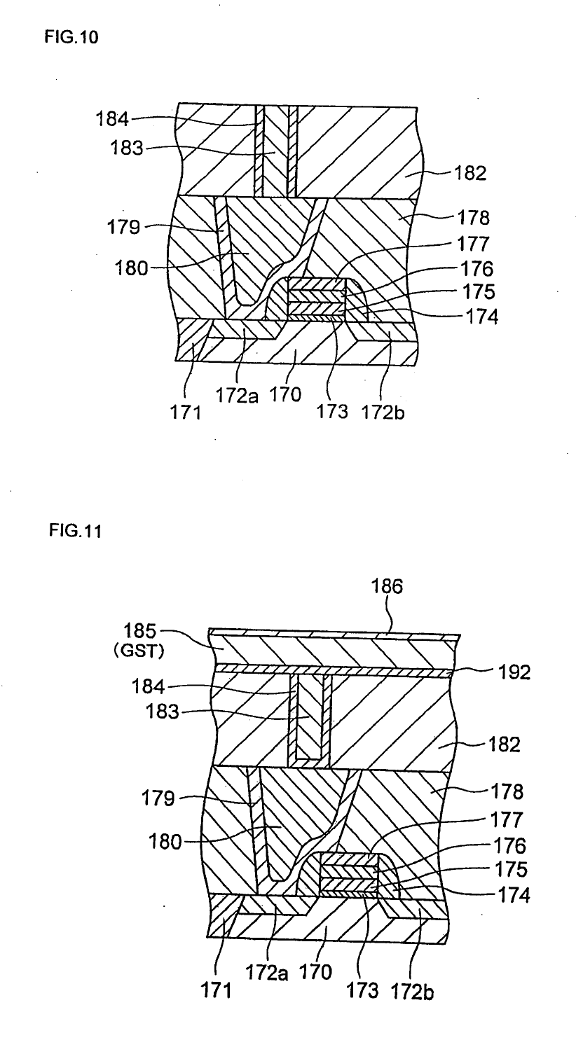

FIG. 10 is a schematic cross-sectional view of a relevant part of a stacked heater electrode, for illustrating a method for manufacturing the stacked heater electrode.

As with the example in FIG. 9A, interlayer insulating film 182 is formed on the top surface of contact plug 180 by using a technique such as HDP. Then, a portion of interlayer insulating film 182 is selectively etched to form contact hole 188.

Then a film of TiN is deposited inside contact hole 188 by a MO-CVD method with Ti [N(CH₃)₂]₄ to a thickness in the range from 1 to 30 nm, preferably from 5 to 15 nm.

The TiN film deposited by the MO-CVD method is etched back as shown in FIG. 10 to remove TiN deposited on the bottom surface of contact hole 188 which corresponds to the hole shown in FIG. 9A to form a spacer made of TiN on the inner side surface of contact hole 188.

Then, a film of TiN is deposited on the exposed surface of a first electrically conductive material by a CVD method with TiCl to a thickness in the range from 20 to 80 nm, preferably 40 to 60 nm. As a result of the CVD process, the space in contact hole 188, except the spacer, is filled with TiN generated by the CVD method.

As with the second exemplary embodiment, a second electrode portion 183 made of a second electrically conductive material having a lower resistivity than that of the first electrically conductive material can be formed in contact with the inner side of the first electrode portion.

Portions of first and second electrode portions 184 and 183 that are formed above interlayer insulating film 182 are polished away by using CMP to form a stacked heater electrode as shown in FIG. 10.

A phase-change layer is separately added on the stacked heater electrode thus provided so that the upper end of each of first and second electrode portions 184 and 183 can be brought into contact with the phase-change layer.

Furthermore, first and second electrode portions 184 and 183 can be provided so that the lower end of each of first and second electrode portions 184 and 183 is brought into contact with contact plug 180 as shown in FIG. 10.

### Fourth Exemplary Embodiment

A fourth exemplary embodiment of the present invention will be described below.

FIG. 11 is a schematic cross-sectional view illustrating a relevant part of a phase-change memory device according to the fourth exemplary embodiment of the present invention.

As shown in FIG. 11, provided on a p-type silicon semiconductor substrate 170 are STI (Shallow Trench Isolation) 171 and n-type diffusion layers 172a and 172b which are part of a component of an NMOS transistor.

Gate insulating film 173 is also formed on p-type silicon semiconductor substrate 170, and doped polysilicon layer 175 and tungsten silicide layer 176 are formed in layers on gate insulating film 173 as a gate electrode.

Silicon nitride film 177 is formed on tungsten silicide layer 176. Spacer 174 is formed on the side surface of the gate electrode. Silicon nitride film 177 and spacer 174 electrically insulate the gate electrode from contact plug 180.

Interlayer insulating film 178 is also formed on p-type silicon semiconductor substrate 170 and contact plug 180 is formed on interlayer insulating film 178. Contact plug 180 is electrically connected to n-type diffusion layer 172a.

Contact plug 180 has barrier metal layer 179 formed on the side that contacts interlayer insulating film 178. Barrier metal layer 179 includes a Ti layer and a TiN layer formed in this order starting from the side that contacts interlayer insulating film 178.

A contact hole provided in the interlayer insulating film 178 is filled with tungsten which contacts barrier metal layer 179 to form contact plug 180.

Interlayer insulating film 182 is formed on interlayer insulating film 178. Formed on interlayer insulating film 182 is a stacked heater electrode including first electrode portion 184 made of a first electrically conductive material and second electrode portion 183 made of a second electrically conductive material.

The lower end of first electrode portion 184 is in contact with contact plug 180. The lower end of second electrode portion 183 is electrically connected to contact plug 180 through first electrode portion 184.

The first electrically conductive material may be a TiN obtained by a MO-CVD method using Ti [N(CH₃)₂]₄ as with the second exemplary embodiment. The second electrically conductive material may be TiN obtained by a CVD method using TiCl.

A material such as TiN that is obtained by using a CVD method contains fewer impurities than a material such as TiN obtained by a MO-CVD. Therefore, second electrode portion 183 that has a lower resistivity than that of the first electrically conductive material can be provided in contact with the inner side of first electrode portion 184.

An insulating film (not shown) is formed on interlayer insulating film 182. Ti thin film 192, which acts as an adhering layer, is formed on the top surface of the insulating film and GST 185, which is a phase-change layer, that is formed on Ti thin film 192. Upper electrode 186 is formed on the top surface of GST 185.

The upper ends of first and second electrode portions 184 and 183 are in contact with the phase-change layer.

The entire upper end of first electrode portion 184 does not necessarily need to be in contact with phase-change layer 185. A portion of the upper end may be in contact with phase-change layer 185.

### Fifth Exemplary Embodiment

A fifth exemplary embodiment of the present invention will be described below.

In this exemplary embodiment, a circuit configuration of a phase-change memory device, a layout configuration of memory cells, and a method for manufacturing a phase-change memory device will be described.

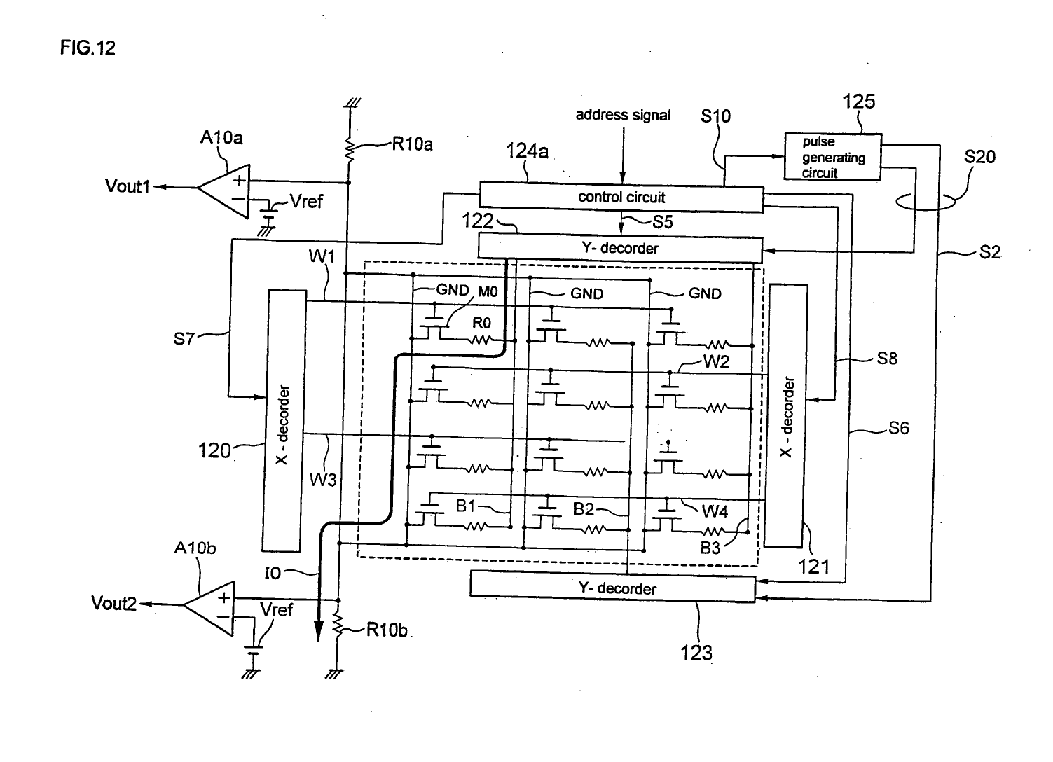

FIG. 12 is a circuit diagram illustrating a circuit configuration of the entire phase-change memory device according to the fourth exemplary embodiment.

As shown in FIG. 12, the phase-change memory device includes a memory cell section at its center and circuitry surrounding the memory cell section.

The memory cell section includes a matrix of multiple memory cells. Each memory cell has a MOS field-effect transistor M0 for selecting an element and a portion including a phase-change layer (shown as an equivalent resistance R0 in FIG. 12).

Connected to the memory cell section are word lines W1-W4, bit lines B1-B3, and ground lines GND which are ground potential lines.

The surrounding circuitry will be described next.

X-decoders 120 and 121 and Y-decoders 122 and 123 are connected to the memory cell section. X-decoders 120 and 121 and Y-decoders 122 and 123 constitute an address circuit. X-decoders 120 and 121 drive word lines W1-W4. Y-decoders 122 and 123 drive bit lines B1-B3.

Control circuit 124 is connected to X-decoders 120 and 121 and Y-decoders 122 and 123. Control circuit 124 centrally controls operation of the phase-change memory device. Address signals are applied to control circuit 124, then control circuit 124 provides control signals S5-S8 to Y-decoders 122 and 123 and X-decoders 120 and 121, respectively, to individually control operation of decoders 120-123.

Pulse generating circuit 125 is connected to control circuit 124 and to Y-decoders 122 and 123. Pulse generating circuit 125 generates various pulse signals (setting, resetting, and reading pulses) S20 in accordance with control signal S10 from control circuit 124 and provides the pulse signals to Y-decoders 122 and 123.

Connected to the ground lines GND are operational amplifiers A10a and A10b constituting a sense circuit and current-to-voltage converting resistances R10a and R10b for converting current I0 (indicated by the thick solid line in FIG. 12) into a voltage. Here, Vref is a reference voltage, and Vout1 and Vout2 are detection signals (read-out signals) of the phase-change memory device.

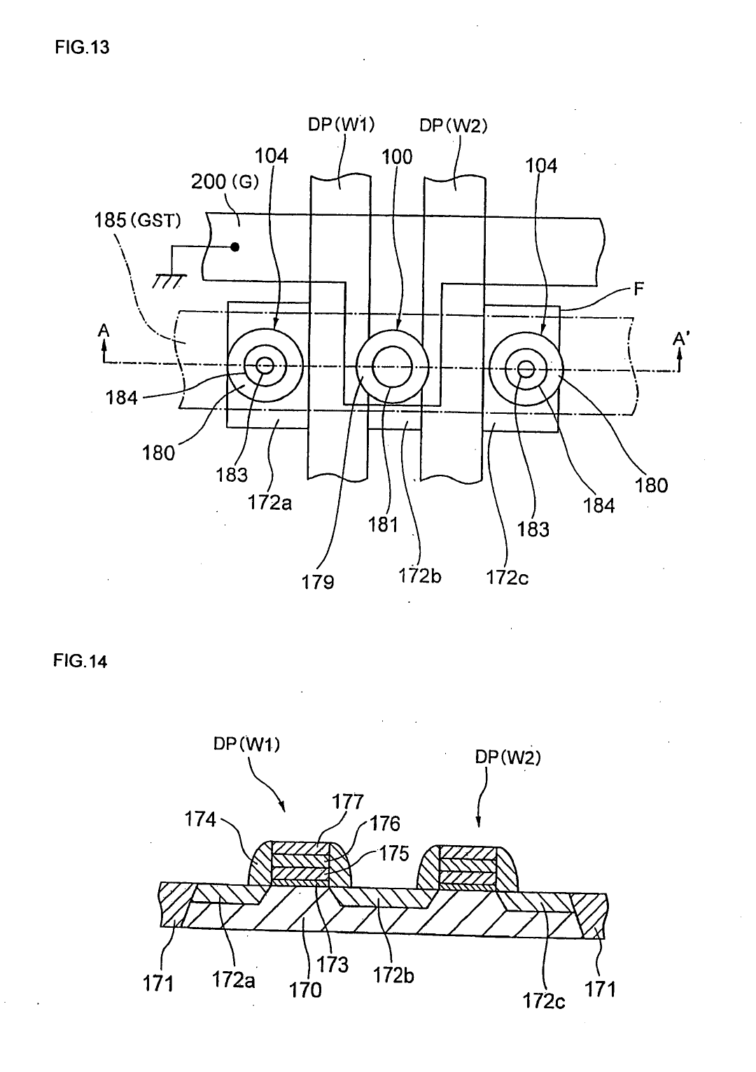

FIG. 13 is a top view showing an exemplary layout of elements and wiring in the memory cell region of the phase-change memory device shown in FIG. 12. The same components in FIG. 13 as those shown in FIG. 11 are labeled with the same reference numerals.

A rectangular region F0 enclosed by a solid line is an element formation region surrounded by an STI.

Two wiring lines DP provided in the vertical direction in FIG. 13 are word lines W1 and W2 formed by a doped polysilicon layer. Each of wiring lines DP also functions as a gate electrode of a MOS field-effect transistor.

Each of stacked heater electrodes disposed on both sides of the two wiring lines DP includes first electrode portion 184 made of a first electrically conductive material and second electrode portion 183 made of a second electrically conductive material.

The first electrically conductive material may be a TiN obtained by a MO-CVD method using Ti [N(CH₃)₂]₄ as with the second exemplary embodiment. The second electrically conductive material may be TiN obtained by a CVD method using TiCl.

Ground potential plug 100 disposed in the center is formed of barrier metal 179 including TiN and Ti, and tungsten 180.

Reference numeral 200 in FIG. 13 denotes a ground line (G). GST 185 (enclosed by the alternate long and short dash line in FIG. 13), which is a phase-change layer, is provided across FIG. 13.

A method for manufacturing a phase-change memory device according to the fifth exemplary embodiment will be described next. One exemplary manufacturing method will be described here. A first processing step forming a switching element for selecting a memory cell in and on a semiconductor substrate will be described first.

FIG. 14 is a schematic cross-sectional view showing a relevant part of a phase-change memory device at the first processing step, taken along line A-A′ of FIG. 13.

As shown in FIG. 14, STI 171 is formed on p-type semiconductor silicon substrate 170 as an element isolating region, and then gate oxide film 173 is formed.

Then, doped polysilicon film 175 having a thickness of 100-nm, tungsten silicide film 176 having a thickness of 100-nm, and silicon nitride film 177 having a thickness of 100-nm, are formed in this order. A photoresist (not shown) is applied on silicon nitride film 177 and the photoresist is processed using photolithography to form an etching mask.

Silicon nitride film 177 is then etched using anisotropic etching such as RIE (Reactive Ion Etching) to remove the resist mask. Silicon nitride film 177 is used as a mask to continuously etch tungsten silicide 176 and doped polysilicon 175 to form a gate electrode.

Phosphorus ions are implanted by using the gate electrode as a mask to form n-type diffusion layers 172a and 172b. A silicon nitride film is deposited on the substrate to a thickness of 50 nm and then is etched back using RIE to form spacer 174.

The gate of the MOS field-effect transistor thus formed is a wiring line DP, namely word line W1, W2, in FIG. 13. The MOS field-effect transistor functions as a switching element for selecting a memory cell.

A second processing step for forming a contact plug that electrically connects to the switching element will be described next.

FIG. 15 is a schematic cross-sectional view showing a relevant part of the phase-change memory device at the second processing step, taken along line A-A′ of FIG. 13.

TEOS oxide film 178, which acts as an interlayer insulating film, is formed on semiconductor silicon substrate 170 to a thickness of 700 nm, and then is planarized by CMP.

A contact hole is formed at a predetermined position in interlayer insulating film 178 using a lithography technique. In doing this, interlayer insulating film 178 is etched under chosen conditions under which the interlayer insulating film 178 is etched but the silicon nitride film is not etched.

A Ti film having a thickness of approximately 10 nm and a TiN film having a thickness of approximately 15 nm are continuously deposited on the inner surface of the contact hole to form barrier metal 179. Then, the contact hole is filled with W and the top surface of W is planarized by CMP to form contact plug 180. Ground line 200 made of W is formed on ground potential plug 105.

A third processing step will be described next in which a portion of an interlayer insulating film formed on the contact plug is selectively etched to form a contact hole.

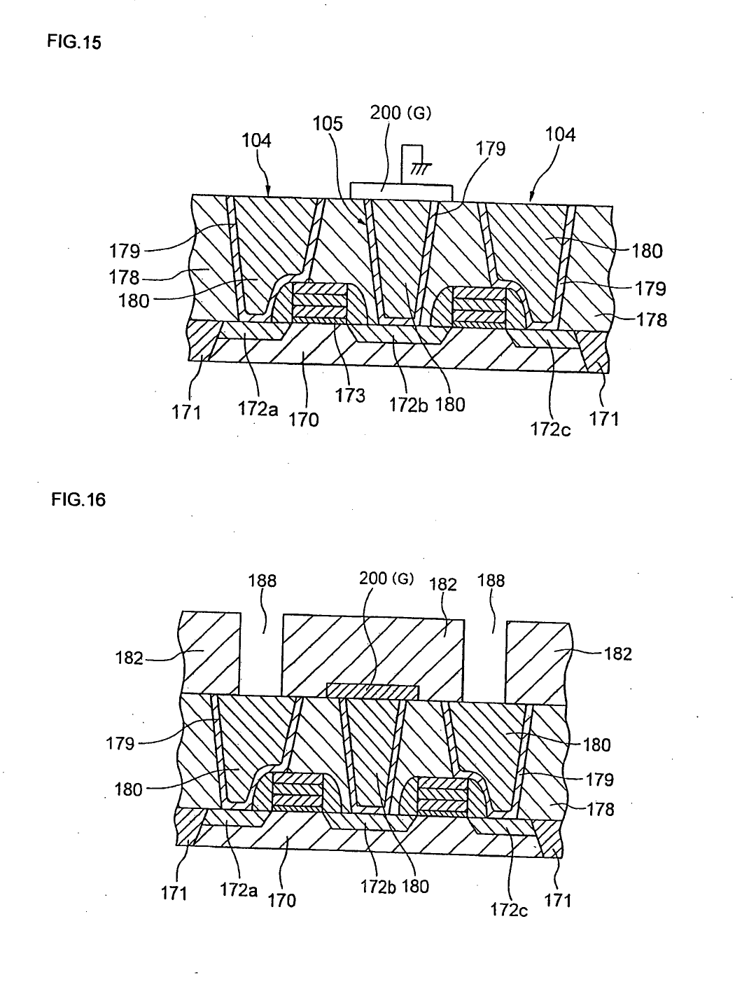

FIG. 16 is a schematic cross-sectional view showing a relevant portion of the phase-change memory device at the third processing step, taken along line A-A′ of FIG. 13.

As shown in FIG. 16, an oxide film, which acts as interlayer insulating film 182, is formed on the substrate shown in FIG. 15 by HDP. Then, a photoresist (not shown) is applied on interlayer insulating film 182 and the photoresist is processed by photolithography to form an etching mask.

A predetermined position in interlayer insulating film 182 is etched by using anisotropic etching such as plasma etching, and then the resist match is removed.

In this way, contact hole 188 is formed in interlayer insulating film 182 in which a stacked heater electrode will be embedded.

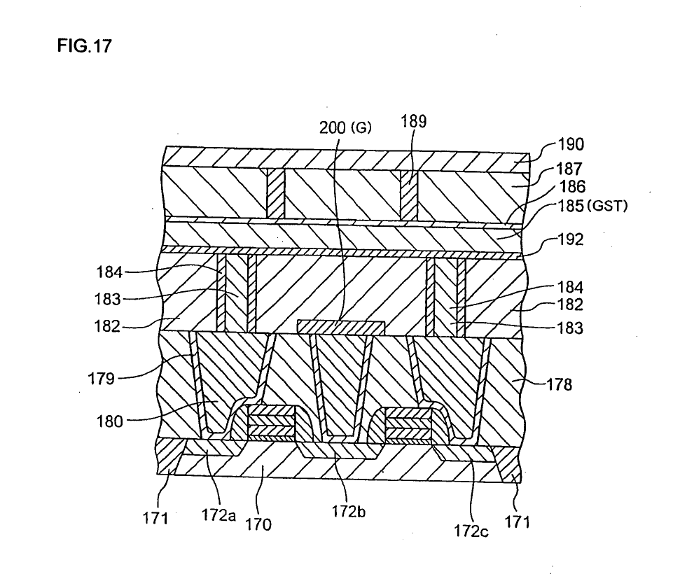

FIG. 17 is a schematic cross-sectional view showing a relevant portion of the phase-change memory device at fourth, fifth, and sixth processing steps, taken along line A-A′ of FIG. 13.

The fourth processing step for depositing a first electrically conductive material in the contact hole and the fifth processing step for depositing a second electrically conductive material on an exposed surface of the first electrically conductive material in the contact hole are the same as those described with respect to the third exemplary embodiment.

In this way, a stacked heater electrode can be provided such that the lower end of first electrode portion 184 made of the first electrically conductive material and the lower end of second electrode portion 183 made of the second electrically conductive material are in contact with contact plug 180.

Then, a photoresist (not shown) is applied on interlayer insulating film 182 and then the photoresist is processed using photolithography to form an etching mask.

A predetermined position in interlayer insulating film 182 is etched using anisotropic etching such as plasma etching and then the resist mask is removed. A thin Ti layer, which acts as adhering layer 192, is formed on the substrate. GST185, which is a phase-change layer, is deposited on Ti layer 192 to a thickness of 100 nm. Then, upper electrode 186 made of W is formed on GST film 185.

Interlayer insulating film 187 is formed on upper electrode layer 186, and a contact hole (not shown) is formed at a predetermined position in interlayer insulating film 187. The contact hole provided in interlayer insulating film 187 is filled with W to form contact plug 189. Then, wiring layer 190 of W is formed. Wiring layer 190 forms bit lines B1-B3 in the circuit diagram of FIG. 12.

According to the process described above, a phase-change memory device of the present invention can be manufactured.

Continuous write testing showed that the phase-change memory device according to the present invention thus provided can be rewritten 10E10 times. In contrast, a phase-change memory device using a heater electrode made of TiN obtained by the MO-CVD method instead of the stacked heater electrode used in the present invention caused malfunctions after 10E6 continuous rewrites in continuous rewrite testing.

While having described exemplary embodiments of the present invention, the present invention is not limited to these. Variations and modifications can be made without departing from the scope of the technical idea of the present invention.

For example, MOS transistors of memory cells can be replaced with various switching elements such as bipolar transistors, junction diodes, or Schottky barrier diodes.

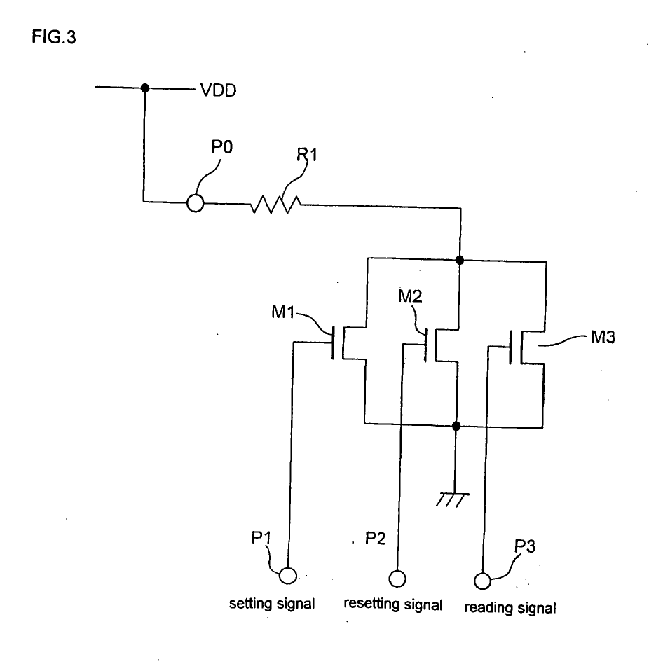

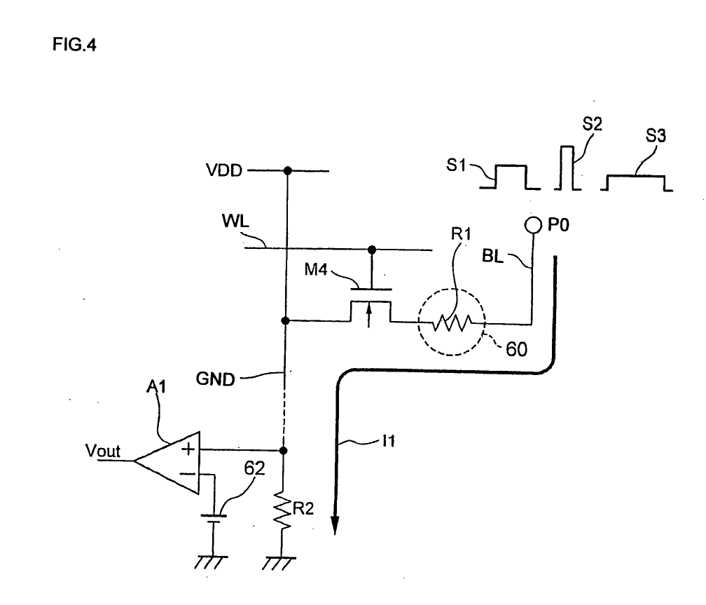

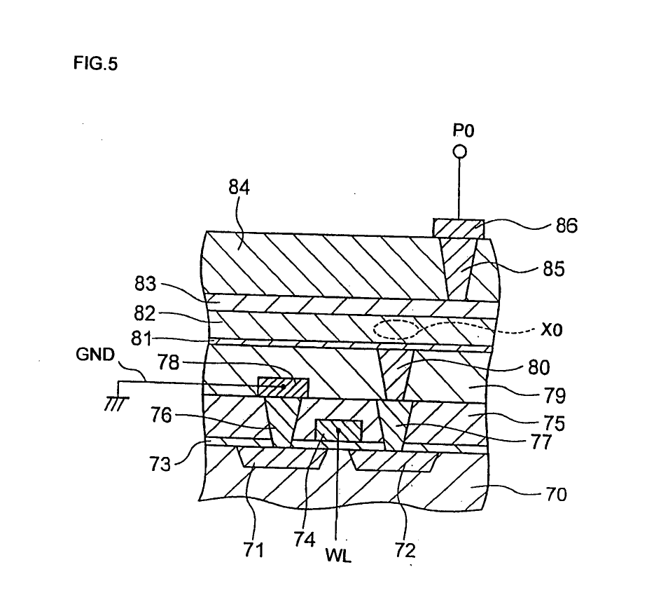

The phase-change layer used in the present invention may be made of a material other than a chalcogenide semiconductor. As the circuit arrangement of the phase-change memory device, a circuit arrangement may be used in which transistors of different sizes are selectively turned on to control a current, instead of the circuit arrangement as shown in FIG. 3 in which pulses having different waveforms are input.

What is claimed is:

1. A phase-change memory device comprising: a phase-change layer; a stacked heater electrode electrically connected to said phase-change layer; and a contact plug electrically connected to said stacked heater electrode, wherein
said stacked heater electrode comprises at least:
a first electrode portion made of a first electrically conductive material; and
a second electrode portion provided in contact with an inner side of said first electrode portion, said second electrode portion being made of a second electrically conductive material having a resistivity lower than a resistivity of said first electrically conductive material.

2. The phase-change memory device according to claim 1, wherein an upper end of said first electrode portion and an upper end of said second electrode portion are in contact with said phase-change layer;
a lower end of said first electrode portion is in contact with said contact plug; and
a lower end of said second electrode portion is electrically connected to said contact plug through said first electrode portion.

3. The phase-change memory device according to claim 1, wherein an upper end of said first electrode portion and an upper end of said second electrode portion are in contact with said phase-change layer; and
a lower end of said first electrode portion and a lower end of said second electrode portion are in contact with said contact plug.

4. The phase-change memory device according to claim 1, wherein said first electrically conductive material includes at least one element selected from a group consisting of titanium, tantalum, molybdenum, niobium, zirconium, tungsten, carbon, titanium nitride, tantalum nitride, molybdenum nitride, tungsten nitride, carbon nitride, titanium silicide, tantalum silicide, molybdenum silicide, niobium silicide, zirconium silicide, tungsten silicide, and carbon silicide.

5. The phase-change memory device according to claim 1, wherein said second electrically conductive material includes at least one element selected from a group consisting of titanium, tantalum, molybdenum, niobium, zirconium, tungsten, carbon, titanium nitride, tantalum nitride, molybdenum nitride, niobium nitride, zirconium nitride, tungsten nitride, carbon nitride, titanium silicide, tantalum silicide, molybdenum silicide, niobium silicide, zirconium silicide, tungsten silicide, and carbon silicide.

6. The phase-change memory device according to claim 1, wherein a resistivity of said first electrically conductive material is at least 10 times the resistivity of said second electrically conductive material.

7. The phase-change memory device according to claim 1, wherein said first electrode portion is made of said first electrically conductive material formed by a Metal Organic-Chemical Vapor Deposition method; and
said second electrode portion is made of said second electrically conductive material formed by a Chemical Vapor Deposition method.

8. The phase-change memory device according to claim 1, further comprising a switching element for selecting a memory cell, wherein any of a plurality of electrodes of said switching element is electrically connected to said contact plug.

9. A method for manufacturing a stacked heater electrode, comprising at least:
selectively etching a portion of an interlayer insulating film formed on a semiconductor substrate to form a contact hole;
depositing a first electrically conductive material in said contact hole; and
depositing a second electrically conductive material on an exposed surface of said first electrically conductive material in said contact hole.

10. The method for manufacturing a stacked heater electrode according to claim 9, wherein said first electrically conductive material is deposited in said contact hole by using a Metal Organic-Chemical Vapor Deposition method; and
said second electrically conducive material is deposited on the exposed surface of said first electrically conductive material by using a Chemical Vapor Deposition method.

11. A method for manufacturing a phase-change memory device, comprising:
forming in or on a semiconductor substrate a switching element for selecting a memory cell;
forming a contact plug which electrically connects to said switching element;
selectively etching a portion of an interlayer insulating film formed on said contact plug to form a contact hole;
depositing a first electrically conductive material in said contact hole;
depositing a second electrically conductive material on an exposed surface of said first electrically conductive material in said contact hole; and
forming a phase-change layer in contact with said first electrically conductive material and said second electrically conductive material.

12. The method for manufacturing a phase-change memory device according to claim 11, wherein, after depositing said first electrically conductive material in said contact hole, said first electrically conductive material formed on said contact plug is selectively etched away to expose a portion of a top surface of said contact plug and then said second electrically conductive material is deposited on an exposed surface of said first electrically conductive material in said contact hole.

13. The method for manufacturing a phase-change memory device according to claim 11, wherein, said first electrically conductive material is deposited in said contact hole by using a Metal Organic-Chemical Vapor Deposition method; and
said second electrically conductive material is deposited on the exposed surface of said first electrically conductive material by using a Chemical Vapor Deposition method.
